(19) United States
(12) Patent Application Publication
(10) Pub. No.: US 2013/0241623 A1
(43) Pub. Date: Sep. 19, 2013

(54) LEVEL SHIFT CIRCUIT

(71) Applicant: RAYDIUM SEMICONDUCTOR CORPORATION, Hsinchu (TW)

(72) Inventors: YU CHUN LIN, KINMEN COUNTY (TW); HUI WEN MIAO, HSINCHU CITY (TW)

(73) Assignee: RAYDIUM SEMICONDUCTOR CORPORATION, HSINCHU (TW)

(21) Appl. No.: 13/796,056

(22) Filed: Mar. 12, 2013

(30) Foreign Application Priority Data
Mar. 19, 2012 (TW) 101109288

(51) Int. Cl. H03K 17/30; H03L 5/00

(52) U.S. Cl. CPC H03K 17/302; H03L 5/00
USPC 327/333

(57) ABSTRACT

A level shift circuit includes a first input terminal, a second input terminal, a first output terminal, a second output terminal, a latch-type level shifter, a first current source and a second current source. The first input terminal receives an input signal; the second input terminal receives an inverse signal of the input signal; the first output terminal outputs an output signal; and the second output terminal outputs an inverse signal of the output signal. The latch-type level shifter is connected to the first input terminal, the second input terminal, the first output terminal and the second output terminal. The first current source is connected between a first high voltage input terminal of the latch-type level shifter and a voltage source. The second current source is connected between a second high voltage input terminal of the latch-type level shifter and the voltage source.

### BACKGROUND

1. Technical Field

The present disclosure relates to a circuit design, and more particularly, to a circuit design of a level shift circuit.

2. Description of Related Arts

The gate driver and the source driver are the most important driving circuits in an LCD panel, and both drivers use a level shift circuit to convert low input voltages into high output voltages; for example, converting an input voltage of 0 to 5 volts into an output voltage higher than 0 to 5 volts, respectively. In particular, the level shift circuit can be adjusted according to the actual application.

FIG. 1 illustrates a conventional latch-type level shift circuit 100. The latch-type level shift circuit 100 comprises transistors 101, 102, 103, and 104. The transistors 101 and 102 are N-type transistors, while the transistors 103 and 104 are P-type transistors. The gate of the transistor 101 is configured to receive a low voltage input (In); the drain of the transistor 101 is configured to output an inverse output (Out_b) of a high voltage output (Out); and the source of the transistor 101 is connected to a low voltage source (ground), wherein the low voltage input (In) is between 0 and 5 volts, and the high voltage output (Out) is between 0 and 40 volts. The gate of the transistor 102 is configured to receive an inverse input (In_b) of the low voltage input (In); the drain of the transistor 102 is configured to output the high voltage output (Out); and the source of the transistor 102 is connected to the low voltage source (ground). The gate of the transistor 103 is connected to the drain of the transistor 102; the drain of the transistor 103 is connected to the drain of the transistor 101; and the source of the transistor 103 is connected to a high voltage source (VDDA). The gate of the transistor 104 is connected to the drain of the transistor 101; the drain of the transistor 104 is connected to the drain of the transistor 102; and the source of the transistor 104 is connected to a high voltage source (VDDA).

During the level shifting process of the latch-type level shift circuit 100, the transistors 101 and 104 turn on if the low voltage input (In) is 5 volts, and the high voltage output (Out) is the high voltage source (VDDA) minus the cross-voltage of the transistor 104; the transistors 102 and 103 turn on if the low voltage input (In) is 0 volts, and the high voltage output (Out) is the low voltage source (ground) plus the cross-voltage of the transistor 102. In fact, the transistors 101 and 103 compete to turn on if the low voltage input (In) is 5 volts during the level shifting process of the latch-type level shift circuit 100. The voltage of the gate of the transistor 101 is only 5 volts, i.e., the voltage between the gate and the source of the transistor 101 is far smaller than the voltage between the gate and the source of the transistor 103. Consequently, to turn on the transistor 101, the width to length ratio of the transistor 101 must be far larger than the width to length ratio of the transistor 102, and the implementation of the latch-type level shift circuit 100 requires a large wafer surface.

FIG. 2 illustrates another conventional level shift circuit 200. The latch-type level shift circuit 200 comprises transistors 201, 202, 203, 204, 205 and 206. The transistors 201 and 202 are N-type transistors, while the transistors 203, 204, 205 and 206 are P-type transistors. Compared to the level shift circuit 100 shown in FIG. 1, the level shift circuit 200 in FIG. 2 further comprises a bias control transistor 205 between the transistors 201 and 203, and a bias control transistor 206 between the transistors 202 and 204. The gates of the bias control transistors 205 and 206 are configured to receive a bias control voltage (Vb) to provide a voltage drop. The level shift circuit 200 uses the bias control transistors 205 and 206 to speed up the shifting of the inverse output (Out_b) and the high voltage output (Out). However, the level shift circuit 200 may possess a high transient is current.

FIG. 3 shows the current waveform of the level shift circuit 200 during the shifting. If the low voltage input (In) is 5 volts during the level shifting process of the latch-type level shift circuit 200, the transient current flowing through the transistors 201, 203 and 205 will be very high, and such high transient current may cause a ground bouncing effect in the driving circuit of the LCD panel.

### SUMMARY

A level shift circuit according to one aspect of the present disclosure comprises a first input terminal, a second input terminal, a first output terminal, a second output terminal, a latch-type level shifter, a first current source and a second current source. The first input terminal is configured to receive an input signal; the second input terminal is configured to receive an inverse signal of the input signal; the first output terminal is configured to output an output signal, and the second output terminal is configured to output an inverse signal of the output signal. The latch-type level shifter is connected to the first input terminal, the second input terminal, the first output terminal and the second output terminal. The first current source is connected between a first high voltage input terminal of the latch-type level shifter and a voltage source. The second current source is connected between a second high voltage input terminal of the latch-type level shifter and the voltage source.

A level shift circuit according to another aspect of the present disclosure comprises a first transistor, a second transistor, a third transistor, a fourth transistor, a fifth transistor and a sixth transistor, wherein the first transistor and the second transistor are N-type transistors; wherein the third transistor, the fourth transistor, the fifth transistor and the sixth transistor are P-type transistors. The first transistor has a gate configured to receive an input signal, a drain configured to output an output signal, and a source connected to a low voltage terminal. The second transistor has a gate configured to receive an inverse signal of the input signal, a drain configured to output an inverse signal of the output signal, and a source connected to the low voltage terminal. The third transistor has a gate connected to the drain of the second transistor and a drain connected to the drain of the first transistor. The fourth transistor has a gate connected to the drain of the first transistor and a drain connected to the drain of the second transistor. The fifth transistor has a gate configured to receive a first bias voltage, a drain connected to a source of the third transistor, and a source connected to a high voltage terminal. The sixth transistor has a gate configured to receive a second bias voltage, a drain connected to a source of the fourth transistor, and a source connected to the high voltage terminal.

A level shift circuit according to another aspect of the present disclosure comprises a first transistor, a second transistor, a third transistor, a fourth transistor, a fifth transistor and a sixth transistor, wherein the first transistor and the second transistor are P-type transistors; wherein the third transistor, the fourth transistor, the fifth transistor and the sixth transistor are N-type transistors. The first transistor has a gate configured to receive an input signal, a drain configured to output an output signal, and a source connected to a high voltage terminal. The second transistor has a gate configured to receive an inverse signal of the input signal, a drain configured to output an inverse signal of the output signal, and a source connected to the high voltage terminal. The third transistor has a gate connected to the drain of the second transistor and a drain connected to the drain of the first transistor. The fourth transistor has a gate connected to the drain of the first transistor and a drain connected to the drain of the second transistor. The fifth transistor has a gate configured to receive a first bias voltage, a drain connected to a source of the third transistor, and a source connected to a low voltage terminal. The sixth transistor has a gate configured to receive a second bias voltage, a drain connected to a source of the fourth transistor, and a source connected to the low voltage terminal.

The foregoing has outlined rather broadly the features and technical advantages of the present disclosure in order that the detailed description of the disclosure that follows may be better understood. Additional features and advantages of the disclosure will be described hereinafter, which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 illustrates a conventional latch-type level shift circuit;

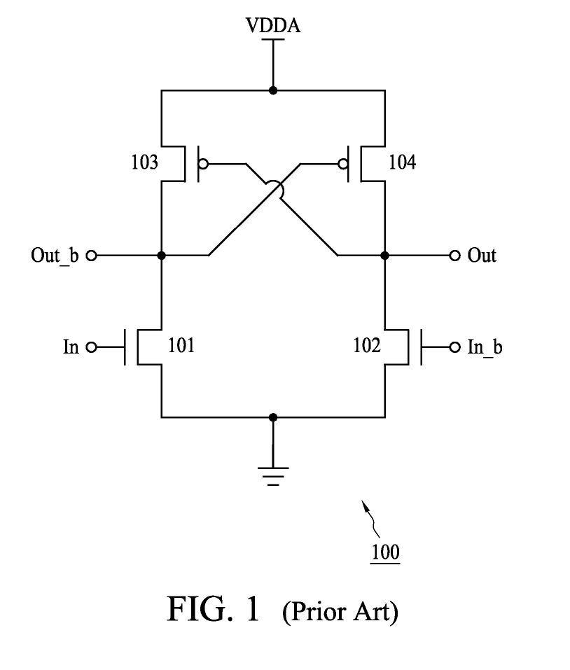

FIG. 2 illustrates another conventional level shift circuit;

FIG. 3 shows the current waveform of the level shift circuit shown in FIG. 2 during the shifting;

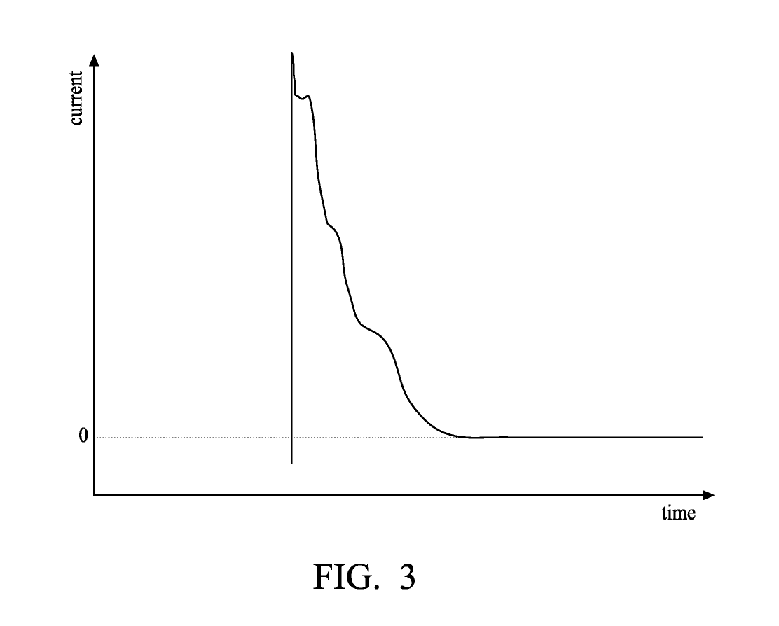

FIG. 4 illustrates a level shift circuit according to one embodiment of the present disclosure;

FIG. 5 illustrates a level shift circuit according to another embodiment of the present disclosure; and

FIG. 6 shows the current waveform of the level shift circuit shown in FIG. 4 during the shifting.

### DETAILED DESCRIPTION

The present disclosure is directed to a level shift circuit. In order to make the present disclosure completely comprehensible, detailed steps and structures are provided in the following description. Obviously, implementation of the present disclosure does not limit special details known by persons skilled in the art. In addition, known structures and steps are not described in detail, so as not to limit the present disclosure unnecessarily. Preferred embodiments of the present disclosure will be described below in detail. However, in addition to the detailed description, the present disclosure may also be widely implemented in other embodiments. The scope of the present disclosure is not limited to the detailed description, and is defined by the claims.

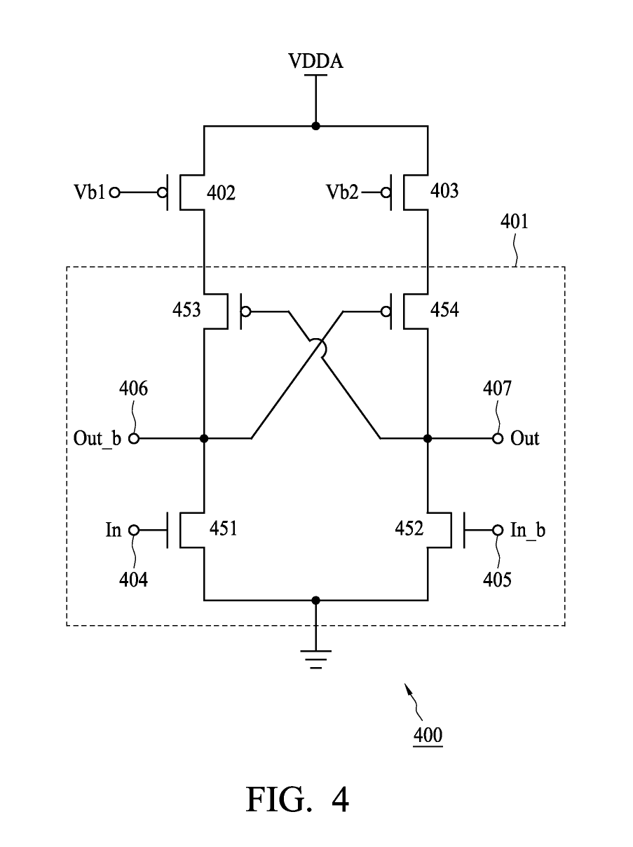

FIG. 4 illustrates a level shift circuit 400 according to one embodiment of the present disclosure. The level shift circuit 400 comprises a latch-type level shifter 401, transistors 402 and 403, a first input terminal 404, a second input terminal 405, a first output terminal 406, and a second output terminal 407. The first input terminal 404 is configured to receive an input signal (In); the second input terminal 405 is configured to receive an inverse signal (In_b) of the input signal; the second output terminal 407 is configured to output an output signal (Out); and the first output terminal 406 is configured to output an inverse signal (Out_b) of the output signal.

The latch-type level shifter 401 comprises transistors 451, 452, 453 and 454, wherein the transistors 451 and 452 are N-type transistors, while the transistors 453 and 454 are P-type transistors. The transistor 451 has a gate connected to the first input terminal 404, a drain connected to the first output terminal 406, and a source connected to a low voltage terminal such as a ground voltage terminal or a negative voltage terminal. The transistor 452 has a gate connected to the second input terminal 405, a drain connected to the second output terminal 407, and a source connected to the low voltage terminal. The transistor 453 has a gate connected to the second output terminal 407, a drain connected to the first output terminal 406, and a source connected to a drain of the transistor 402. The transistor 454 has a gate connected to the first output terminal 406, a drain connected to the second output terminal 407, and a source connected to a drain of the transistor 403. The transistor 402 is a P-type transistor having a gate configured to receive a first bias voltage (Vb1) and a source connected to a high voltage source (VDDA). The transistor 403 is a P-type transistor having a gate configured to receive a second bias voltage (Vb2) and a source connected to the high voltage source (VDDA).

In one embodiment of the present invention, the voltage range of the high voltage source (VDDA) is between 0 and 40 volts, and the voltage range of the input signal (In) is between 0 and 5 volts. Consequently, the voltage range of the output signal (Out) is between 0 and 40 volts, omitting the cross-voltage of the transistor. In another embodiment of the present invention, the voltage range of the high voltage source (VDDA) may be changed to a higher level, and the voltage range of the input signal (In) may be changed to another level, depending on the application of the level shift circuit.

To operate the level shift circuit 400, the first bias voltage (Vb1) and the second bias voltage (Vb2) are designed to be slightly smaller than the voltage of the high voltage source (VDDA) such that the transistors 402 and 403 have a relatively smaller cross-voltage between the gate and the source. Consequently, the transistors 402 and 403 can be considered current sources that provide small, constant current. If the input signal (In) is 5 volts during the level shifting process of the latch-type level shift circuit 400, the transistors 451 and 453 compete to turn on; similarly, if the input signal (In) is 0 volts during the level shifting process of the latch-type level shift circuit 400, the transistors 452 and 454 compete to turn on. However, the current flowing from the high voltage source (VDDA) through the transistors 402, 453 and 451 is the equivalent current provided by the transistor 402 serving as a constant current source; similarly, the current flowing from the high voltage source (VDDA) through the transistors 403, 454 and 452 is the equivalent current provided by the transistor 403 serving as a constant current source. Consequently, the transient current of the level shift circuit 400 during the shifting process is restricted to the equivalent current provided by the transistors 402 and 403 serving as constant current sources.

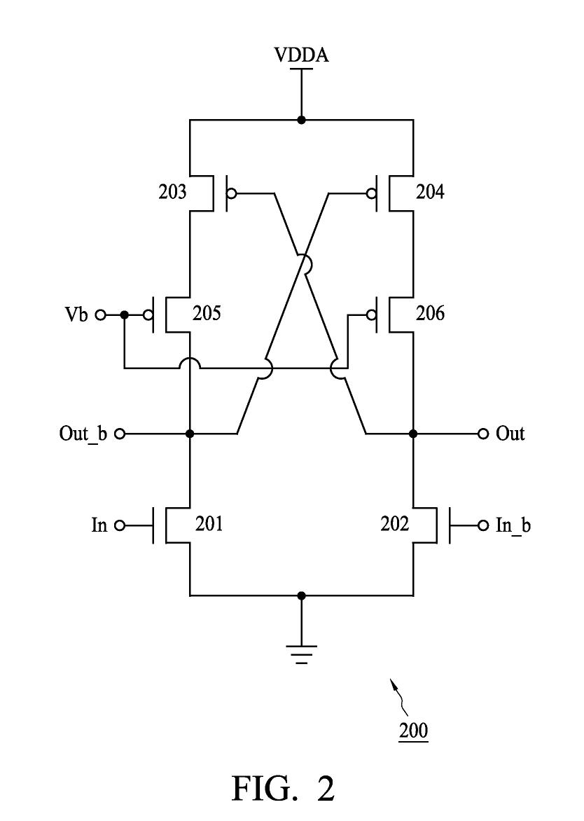

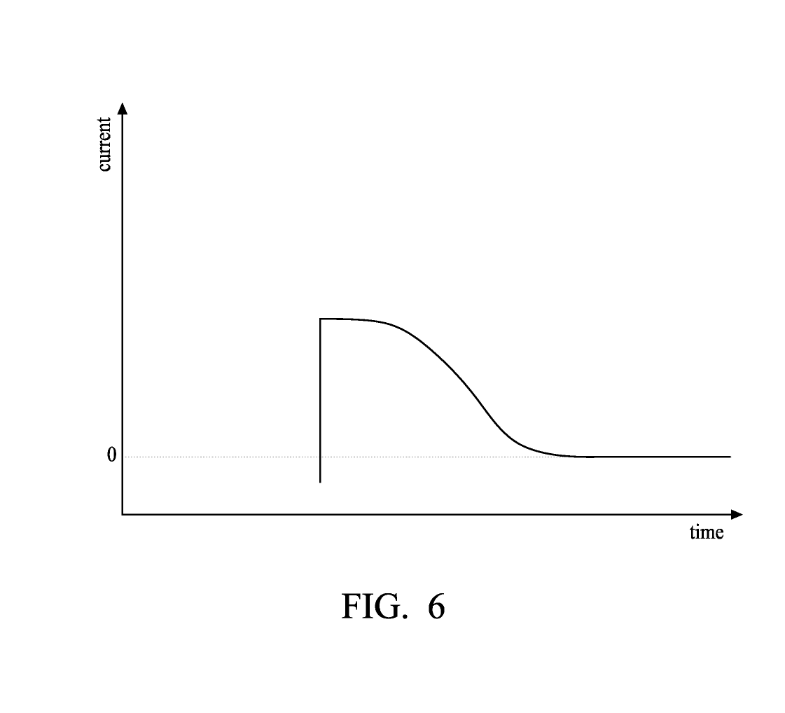

FIG. 6 shows the current waveform of the level shift circuit 400 during the shifting. Comparing the current waveform of the level shift circuit 400 in FIG. 6 with the current waveform of the level shift circuit 200 in FIG. 2, one can see that the level shift circuit 400 has a smaller transient current, and the ground bouncing effect in the driving circuit of the LCD panel can be effectively resolved.

Furthermore, because the transient current of the level shift circuit 400 is very small during the shifting, turning on the latch-type level shifter 401 only needs a relatively smaller driving current. In other words, implementing the level shift circuit 400 needs the transistors 402, 403, 451, 452, 453 and 454 with a smaller width to length ratio. Compared to the conventional level shift circuit 300, the level shift circuit 400 occupies a smaller wafer area, and the fabrication cost of the level shift circuit 400 can be decreased.

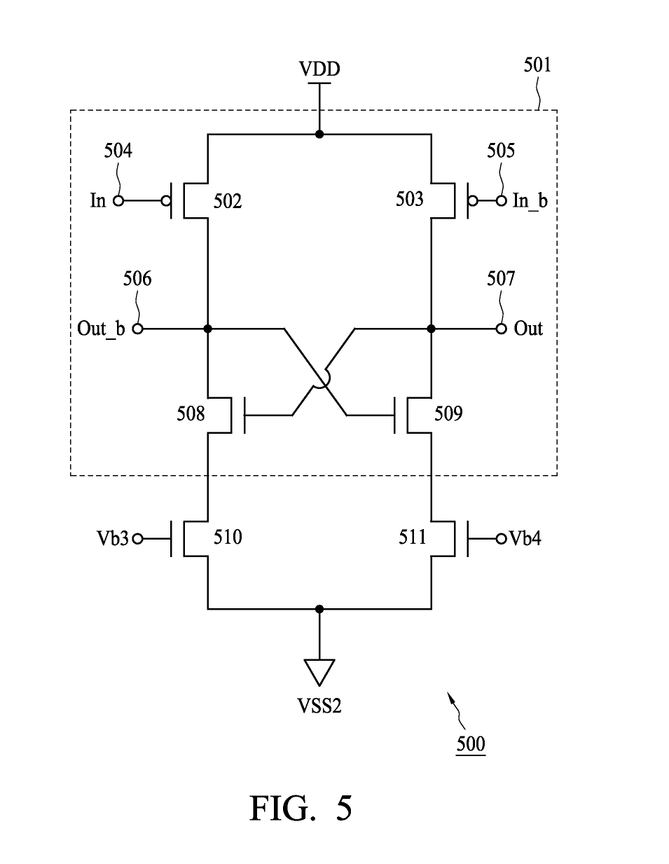

FIG. 5 illustrates a level shift circuit 500 according to another embodiment of the present disclosure. The level shift circuit 500 comprises a latch-type level shifter 501 including transistors 502 and 503, a third input terminal 504, a fourth input terminal 505, a third output terminal 506, and a fourth output terminal 507. The third input terminal 504 is configured to receive a first input signal (In); the fourth input terminal 505 is configured to receive a second input signal (an inverse signal (In_b) of the first input signal); the fourth output terminal 507 is configured to output an output signal (Out); and the third output terminal 506 is configured to output an inverse signal (Out_b) of the output signal.

The latch-type level shifter 501 comprises transistors 508, 509, 502 and 503, wherein the transistors 508 and 509 are N-type transistors, while the transistors 502 and 503 are P-type transistors. The transistor 502 has a gate connected to the third input terminal 504, a drain connected to a source of the transistor 508, and a source connected to a high voltage terminal (VDD). The transistor 503 has a gate connected to the fourth input terminal 505, a drain connected to the source of the transistor 509, and a source connected to the high voltage terminal (VDD). The transistor 508 has a gate connected to the drain (the fourth output terminal 507) of the transistor 503, a drain connected to the third output terminal 506, and a source connected to a drain of the transistor 510. The transistor 509 has a gate connected to the drain (the third output terminal 506) of the transistor 502, a drain connected to the fourth output terminal 507, and a source connected to a drain of the transistor 511. The transistor 510 is a N-type transistor having a gate configured to receive a bias voltage (Vb3) and a source connected to a low voltage terminal (VSS2) such as a ground voltage terminal or a negative voltage terminal. The transistor 511 is a N-type transistor having a gate configured to receive a bias voltage (Vb4) and a source connected to the low voltage terminal (VSS2).

In one embodiment of the present invention, the voltage range of the high voltage source (VDD) is between 0 and 5 volts, the low voltage source is VSS2, and the voltage range of the input signal (In) is between 0 and 5 volts. Consequently, the voltage range of the output signal (Out) is between VDD and VSS2, omitting the cross-voltage of the transistor. In another embodiment of the present invention, the voltage range of the high voltage terminal (VDD) may be changed to another level, and the voltage range of the input signal (In) may be changed to another level, depending on the application of the level shift circuit.

In conclusion, the level shift circuit of the present disclosure fixes the transient current during the shifting so as to decrease the transient current and the occupied wafer area of the level shift circuit. In addition, the level shift circuit of the present disclosure has a symmetric transistor layout, which can facilitate the fabrication yield rate.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A level shift circuit, comprising:
a first input terminal configured to receive an input signal;
a second input terminal configured to receive an inverse signal of the input signal;
a first output terminal configured to output an output signal;
a second output terminal configured to receive an inverse signal of the output signal;
a latch-type level shifter electrically connected to the first input terminal, the second input terminal, the first output terminal, and the second output terminal;
a first current source electrically connected between a first high voltage input terminal of the latch-type level shifter and a voltage source; and
a second current source electrically connected between a second high voltage input terminal of the latch-type level shifter and the voltage source.

2. The level shift circuit of claim 1, wherein the first current source comprises a P-type transistor having a gate connected to a first bias voltage, a source connected to the voltage source, and a drain connected to the latch-type level shifter.

3. The level shift circuit of claim 1, wherein the second current source comprises a P-type transistor having a gate connected to a second bias voltage, a source connected to the voltage source, and a drain connected to the latch-type level shifter.

4. The level shift circuit of claim 1, wherein the first current source comprises a P-type transistor having a gate connected to a first bias voltage, a source connected to the voltage source, and a drain connected to the latch-type level shifter; and the second current source comprises a P-type transistor having a gate connected to a second bias voltage, a source connected to the voltage source, and a drain connected to the latch-type level shifter.

5. The level shift circuit of claim 1, being disposed in a driving circuit of an LCD panel.

6. A level shift circuit, comprising:
a first transistor having a gate configured to receive an input signal, a drain configured to output an output signal, and a source connected to a low voltage terminal;
a second transistor having a gate configured to receive an inverse signal of the input signal, a drain configured to output an inverse signal of the output signal, and a source connected to the low voltage terminal,
a third transistor having a gate connected to the drain of the second transistor and a drain connected to the drain of the first transistor;
a fourth transistor having a gate connected to the drain of the first transistor and a drain connected to the drain of the second transistor;
a fifth transistor having a gate configured to receive a first bias voltage, a drain connected to a source of the third transistor, and a source connected to a high voltage terminal; and
a sixth transistor having a gate configured to receive a second bias voltage, a drain connected to a source of the fourth transistor, and a source connected to the high voltage terminal;
wherein the first transistor and the second transistor are N-type transistors;
wherein the third transistor, the fourth transistor, the fifth transistor and the sixth transistor are P-type transistors.

7. The level shift circuit of claim 6, being disposed in a driving circuit of an LCD panel.

8. A level shift circuit, comprising:
a first transistor having a gate configured to receive an input signal, a drain configured to output an output signal, and a source connected to a high voltage terminal;
a second transistor having a gate configured to receive an inverse signal of the input signal, a drain configured to output an inverse signal of the output signal, and a source connected to the high voltage terminal;
a third transistor having a gate connected to the drain of the second transistor and a drain connected to the drain of the first transistor;
a fourth transistor having a gate connected to the drain of the first transistor and a drain connected to the drain of the second transistor;
a fifth transistor having a gate configured to receive a first bias voltage, a drain connected to a source of the third transistor, and a source connected to a low voltage terminal; and
a sixth transistor having a gate configured to receive a second bias voltage, a drain connected to a source of the fourth transistor, and a source connected to the low voltage terminal;
wherein the first transistor and the second transistor are P-type transistors;
wherein the third transistor, the fourth transistor, the fifth transistor and the sixth transistor are N-type transistors.

9. The level shift circuit of claim 8, being disposed in a driving circuit of an LCD panel.
